(19) United States
(12) Patent Application Publication
(10) Pub. No.: US 2023/0271761 A1
(43) Pub. Date: Aug. 31, 2023

(54) COVER TAPE AND ELECTRONIC-COMPONENT PACKAGE

(71) Applicant: Denka Company Limited, Chuo-ku, Tokyo (JP)

(72) Inventors: Keisuke NABA, Chuo-ku, Tokyo (JP); Gosuke NAKAJIMA, Chuo-ku, Tokyo (JP); Takanori ATSUSAKA, Chuo-ku, Tokyo (JP); Hisatsugu TOKUNAGA, Chuo-ku, Tokyo (JP)

(73) Assignee: Denka Company Limited, Chuo-ku, Tokyo (JP)

(21) Appl. No.: 18/040,173

(22) PCT Filed: Aug. 18, 2021
(86) PCT No.: PCT/JP2021/030215

§ 371 Date: Feb. 1, 2023

(30) Foreign Application Priority Data
Aug. 24, 2020 (JP) 2020-140976
Dec. 22, 2020 (JP) 2020-212246

(51) Int. Cl. B65D 75/28

(52) U.S. Cl. CPC B65D 75/28

(57) ABSTRACT

This cover tape has at least a base layer and a heat seal layer, wherein the heat seal layer contains a copolymer (A) of a styrene-based hydrocarbon and a conjugated diene-based hydrocarbon, the component (A) contains a block copolymer (A-1) of 10% by mass or more and less than 50% by mass of a styrene-based hydrocarbon and more than 50% by mass and 90% by mass or less of a conjugated diene-based hydrocarbon, and a block copolymer (A-2) of 50% by mass or more and 95% by mass or less of a styrene-based hydrocarbon and 5% by mass or more and 50% by mass or less of a conjugated diene-based hydrocarbon, a content of the component (A-1) is 35 to 60% by mass based on a total amount of the heat seal layer, and a mass ratio of the component (A-2) to the component (A-1) is 0.30 to 1.0.

### TECHNICAL FIELD

The present invention relates to a cover tape and an electronic component package.

### BACKGROUND ART

Along with the miniaturization of electronic devices, the electronic components used are becoming smaller and having a higher performance. In the process of assembling electronic devices, components are automatically mounted on printed circuit boards. For transporting such electronic components for surface mounting, an electronic component package in which electronic components are accommodated in a carrier tape in which pockets are continuously thermoformed to match shapes of the electronic components is used to continuously supply the electronic components.

The electronic component package is manufactured by accommodating the electronic components in the pockets of the carrier tape, then stacking a cover tape having a heat seal layer as a cover material on an upper surface of the carrier tape and continuously heat sealing both ends of the cover tape in a longitudinal direction with a heated seal bar (for example, refer to Patent Literature 1).

When the electronic component package is used, the cover tape is peeled off from the carrier tape, and the electronic components are automatically taken out and surface-mounted on an electronic circuit board.

### CITATION LIST

### Patent Literature

[Patent Literature 1] Japanese Unexamined Patent Publication No. 2010-173673

### SUMMARY OF INVENTION

### Technical Problem

In recent years, the electronic components have become significantly smaller, thinner, and lighter, and when the cover tape is peeled off from the carrier tape in a process in which electronic components are mounted on an electronic circuit board, and a difference between the maximum value and the minimum value of the peel strength (hereinafter referred to as a “peel strength range”) becomes too large, there is a problem that the carrier tape vibrates violently, and the electronic components are caused to pop out, which makes mounting defects more likely to occur.

Therefore, the present inventors focused on a heat seal layer of the cover tape and studied a design of the heat seal layer to reduce the peel strength range. Since the cover tape is generally supplied in the form of a wound body when the electronic component package is manufactured, it is necessary to consider blocking resistance as well.

The present invention has been made in view of the above circumstances, and an object of the present invention is to provide a cover tape that has sufficient blocking resistance and is capable of reducing a peel strength range, and an electronic component package using the same.

### Solution to Problem

In order to solve the above problems, one aspect of the present invention provides a cover tape including at least a base layer and a heat seal layer, wherein the heat seal layer contains a copolymer (A) of a styrene-based hydrocarbon and a conjugated diene-based hydrocarbon, the component (A) contains a block copolymer (A-1) of 10% by mass or more and less than 50% by mass of a styrene-based hydrocarbon and more than 50% by mass and 90% by mass or less of a conjugated diene-based hydrocarbon, and a block copolymer (A-2) of 50% by mass or more and 95% by mass or less of a styrene-based hydrocarbon and 5% by mass or more and 50% by mass or less of a conjugated diene-based hydrocarbon, a content of the component (A-1) is 35 to 60% by mass based on a total amount of the heat seal layer, and a mass ratio of the component (A-2) to the component (A-1) is 0.30 to 1.0.

The above-described cover tape is less likely to cause blocking even when it is manufactured in the form of a wound body, and a peel strength range can be reduced when the cover tape is peeled off after heat sealing. Thus, in the manufacture of an electronic component package, it is possible to curb a failure in unwinding of the cover tape from the wound body, and in the manufacture of electronic equipment, when the cover tape is peeled off from the electronic component package, it is possible to prevent the electronic components from popping out and to prevent defective mounting on an electronic circuit board.

The heat seal layer may further contain an ethylene-based polymer (B) from the viewpoints of making it easier to develop sealing properties with less heat energy and of curbing blocking.

The component (B) may contain one or more of an ethylene-α-olefin copolymer and an ethylene-methyl (meth)acrylate copolymer from the viewpoint of film-forming properties in addition to the above-described points.

Another aspect of the present invention provides an electronic component package including a carrier tape having an accommodating portion, electronic components accommodated in the accommodating portion of the carrier tape, and the cover tape heat-sealed to the carrier tape as a cover material.

The above-described electronic component package may have a small peel strength range when the cover tape is peeled off. Thus, in the manufacture of electronic equipment, it is possible to greatly reduce the defective mounting rate of electronic components.

### Advantageous Effects of Invention

According to the present invention, it is possible to provide a cover tape that has sufficient blocking resistance and is capable of reducing a peel strength range, and an electronic component package using the same.

### BRIEF DESCRIPTION OF DRAWINGS

FIG. 1 is a schematic cross-sectional view showing an embodiment of a cover tape.

FIG. 2 is a partially cutaway perspective view showing an embodiment of an electronic component package.

FIG. 3 is a diagram describing a peel strength range

### DESCRIPTION OF EMBODIMENTS

Hereinafter, exemplary embodiments of the present invention are described in detail.

[Cover Tape]

A cover tape of the present embodiment includes at least a base layer and a heat seal layer.

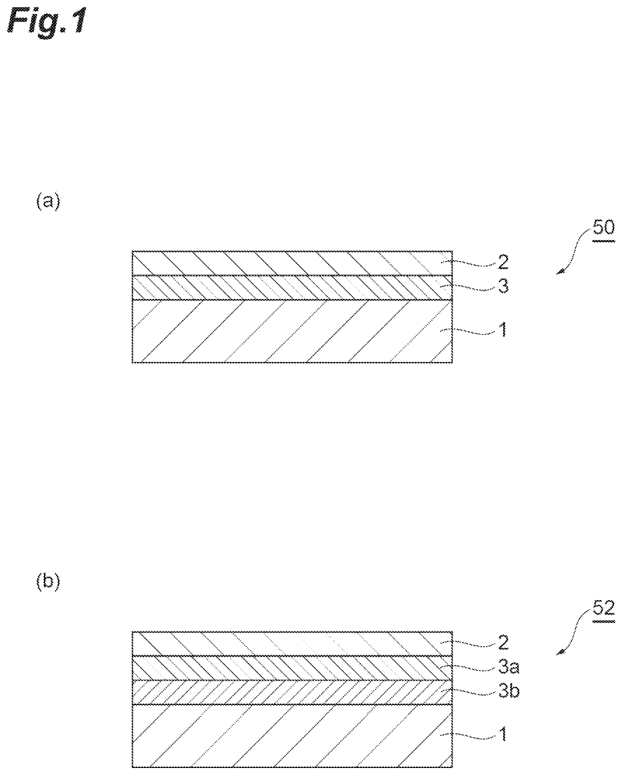

FIG. 1 is a schematic cross-sectional view showing an embodiment of a cover tape. The cover tape 50 shown in FIG. 1(a) includes a base layer 1, a heat seal layer 2 provided on one side of the base layer 1, and an intermediate layer 3 provided between the base layer 1 and the heat seal layer 2. Further, a cover tape 52 shown in FIG. 1(b) includes two intermediate layers 3a and 3b provided between the base layer 1 and the heat seal layer 2. The cover tape of the present embodiment may have a two-layer structure without the intermediate layer, and may have a structure in which a layer such as an antistatic layer is further provided on the side of the base layer 1 opposite to the heat seal layer 2, for example. In addition, the cover tape of the present embodiment may have a structure in which a layer such as an antistatic layer is further provided on the side of the heat seal layer 2 opposite to the base layer 1 as long as heat sealing properties of the heat seal layer are not impaired.

(Base Layer)

The base layer may be a film formed from a resin composition containing one or more thermoplastic resins selected from a polyester resin such as polyethylene terephthalate and polyethylene naphthalate, a polyolefin-based resin such as polypropylene, a polyamide-based resin such as nylon, a polystyrene-based resin, a polyethylene-based resin and a polycarbonate resin. The films are preferably biaxially stretched films from the viewpoint of mechanical strength, and more preferably biaxially stretched polyethylene terephthalate films from the viewpoint of transparency and toughness.

Examples of the polystyrene-based resin include polymers having a styrene unit in a molecular chain at a molar ratio of ½ or more, such as polystyrene, high impact polystyrene (HIPS), styrene-butadiene copolymers or hydrogenated products thereof, styrene-isoprene copolymers or hydrogenated products thereof, graft copolymers of styrene and ethylene, styrene-butene-butadiene copolymers, and copolymers of methacrylic acid and styrene, and the like. The polymers may be used singly or in combination of two or more (as a mixture).

Examples of the polyethylene resin include those having an ethylene unit in the molecular chain at a molar ratio of ½ or more, such as low-density polyethylene, linear low-density polyethylene, ultra-low-density polyethylene, ethylene-α-olefin, ethylene-vinyl acetate copolymer, ethylene-(meth)acrylic acid copolymer, ethylene-methyl (meth)acrylate copolymer, ethylene-ethyl (meth)acrylate copolymer, and ethylene-propylene rubber. They can be used singly or in combination of two or more (as a mixture).

Various additives such as antioxidants and lubricants that are commonly used may be added to the base layer from the viewpoint of obtaining extrusion stability when a film is formed.

The base layer may be a single layer or may have a multilayer structure.

A thickness of the base layer may be 5 to 100 nm, 10 to 80 μm, or 12 to 30 μm from the viewpoint of mechanical strength and heat transfer during heat sealing.

(Intermediate Layer)

The intermediate layer may be provided for the purpose of strengthening adhesive strength between the base layer and the heat seal layer and may include a thermoplastic resin. Examples of the thermoplastic resin include:
(i) a polyethylene resin such as low-density polyethylene, linear low-density polyethylene, and ultra-low-density polyethylene,
(ii) ethylene-1-butene, a copolymer of ethylene and unsaturated carboxylic acid, an ethylene-(meth)acrylic acid ester copolymer, an ethylene-vinyl acetate copolymer, and also a terpolymer with an acid anhydride, and a mixture thereof,
(iii) a styrene-ethylene graft copolymer, a styrene-propylene graft copolymer, a block copolymer of styrene-ethylene-butadiene, and a mixture thereof, and the like.

The thermoplastic resin is preferably a polyethylene-based resin, more preferably a low-density polyethylene resin or a linear low-density polyethylene resin, in view of the above purpose and easy layer formation.

Also, the intermediate layer may have a structure of two or more layers. In this case, due to production of a coextruded film of the heat seal layer and the intermediate layer, extrusion stability of the heat seal layer can be enhanced, while the adhesion between the coextruded film and the base layer can be improved by another intermediate layer. The intermediate layer having a structure of two or more layers may be, for example, a first intermediate layer in which the side in contact with the heat seal layer includes one or more of the resins shown in (i), (ii) and (iii) above, and may be a second intermediate layer in which the side in contact with the base layer includes one or more of the resins shown in (i) and (ii) above.

From the viewpoint of obtaining the extrusion stability during film formation, the intermediate layer may contain various additives such as antioxidants and lubricants that are commonly used.

A thickness of the intermediate layer may be 3 to 70 μm, 5 to 60 μm, or 10 to 50 μm, from the viewpoint of securing adhesive strength between the base layer and the heat seal layer and peel strength of the cover tape.

The cover tape of the present embodiment may have two or more of base layers and/or intermediate layers. In such a cover tape, for example, the base layer and the intermediate layer may have a three-layer structure of a base layer, an intermediate layer and a base layer, or may have a four-layer structure of an intermediate layer, a base layer, an intermediate layer, and a base layer.

When the cover tape of the present embodiment has two or more base layers and/or intermediate layers, a known adhesive can be used to strengthen the adhesion between the layers. Examples of the adhesive include an isocyanate adhesive and an ethyleneimine adhesive. An adhesive layer preferably has a thickness of 5 μm or less from the viewpoint of preventing large variations in the peel strength of the cover tape.

(Heat Seal Layer)

The heat seal layer contains a copolymer (A) of a styrene-based hydrocarbon and a conjugated diene-based hydrocarbon (hereinafter, it may be referred to as component (A)).

The styrene-based hydrocarbon may include styrene, α-methylstyrene, and various alkyl-substituted styrenes. The conjugated diene-based hydrocarbons may include butadiene and isoprene.

The component (A) may contain a block copolymer (A-1) (hereinafter, it may be referred to as a component (A-1)) of 10% by mass or more and less than 50% by mass of a styrene-based hydrocarbon and more than 50% by mass and 90% by mass or less of a conjugated diene-based hydrocarbon, and a block copolymer (A-2) (hereinafter, it may be referred to as a component (A-2)) of 50% by mass or more and 95% by mass or less of a styrene-based hydrocarbon and 5% by mass or more and 50% by mass or less of a conjugated diene-based hydrocarbon.

Examples of the component (A-1) include a styrene-butadiene copolymer, a styrene-butylene-butylene-styrene copolymer, a styrene-ethylene-butylene-styrene copolymer, a styrene-ethylene-propylene-styrene copolymer, and a styrene-isoprene-styrene copolymer. The component (A-1) can be used singly or in combination of two or more.

A mass ratio between the styrene-based hydrocarbon and the conjugated diene-based hydrocarbon in the component (A-1) may be 10/90 to 45/55, may be 30/70 to 45/55, or may be 35/75 to 45/55 from the viewpoint of easy adjustment of the peel strength and film formation properties.

A content of the component (A-1) can be 35 to 60% by mass, may be 40 to 55% by mass, or may be 40 to 50% by mass based on a total amount of the heat seal layer from the viewpoint of a reduction in the peel strength range, and the blocking resistance.

Examples of the component (A-2) may include a styrene-butadiene copolymer, a styrene-butylene-butylene-styrene copolymer, a styrene-ethylene-butylene-styrene copolymer, a styrene-ethylene-propylene-styrene copolymer, and a styrene-isoprene-styrene copolymer. The component (A-2) can be used singly or in combination of two or more.

A mass ratio of the styrene-based hydrocarbon and the conjugated diene-based hydrocarbon in the component (A-2) may be 50/50 to 95/5, may be 70/30 to 90/10, or may be 80/20 to 85/15.

A mass ratio of the component (A-2) to the component (A-1) may be 0.30 to 1.0, may be 0.50 to 0.90, and may be 0.65 to 0.85 from the viewpoint of the reduction in the peel strength range, and the blocking resistance.

A total content of the component (A-1) and the component (A-2) in the heat seal layer may be 50 to 100% by mass, may be 60 to 100% by mass, or may be 70 to 90% by mass based on the total amount of the heat seal layer from the viewpoint of the film formation properties and the blocking resistance of the film.

The heat seal layer may contain a polystyrene-based resin other than the component (A). Examples of such a polystyrene-based resin may include a high impact polystyrene, a general-purpose polystyrene, an acrylonitrile-butadiene-styrene copolymer, and a styrene-ethylene-propylene-styrene copolymer.

A content of the polystyrene-based resin other than the component (A) may be more than 0% by mass and 25% by mass or less, may be 5 to 20% by mass, or may be 5 to 10% by mass, based on the total amount of the heat seal layer from the viewpoint of blocking resistance.

When the heat seal layer contains the (A-1) component, the (A-2) component, and a high impact polystyrene (hereinafter, it may be referred to as a (A-3) component), there may be 35 to 60 parts by mass of the component (A-1), there may be 20 to 40 parts by mass of the component (A-2), and there may be 5 to 15 parts by mass of the component (A-3) with respect to a total of 100 parts by mass of the components (A-1), (A-2) and (A-3).

The heat seal layer can further contain an ethylene-based polymer (B) (hereinafter, it may be referred to as a component (B)) from the viewpoints of making it easier to develop sealing properties with less heat energy and of curbing blocking.

Examples of the component (B) may include an ethylene-α-olefin copolymer (B-1) (hereinafter, it may be referred to as a component (B-1)) and an ethylene-(meth)acrylic acid copolymer (B-2) (hereinafter, it may be referred to as a component (B-2)) from the viewpoint of film formation properties in addition to the above-described points. The heat seal layer may contain one or both of the components (B-1) and (B-2). Further, the component (B) may contain one or more of an ethylene-α-olefin copolymer and an ethylene-methyl (meth)acrylate copolymer from the viewpoint of making it easier to develop sealing properties with less heat energy, blocking suppression, and film formation properties.

Examples of α-olefin in the ethylene-α-olefin copolymer may include propylene, butene, pentene, hexane, and the like.

As the component (B-1), a random copolymer having a structure in which an ethylene component and an α-olefin component are randomly arranged can be used. Examples of such a copolymer may include an ethylene-butene-1 random copolymer and an ethylene-propylene-1 random copolymer.

A proportional ethylene content of the component (B-1) may be 50 to 95% by mass, may be 70 to 95% by mass, or may be 80 to 95% by mass from the viewpoint of making it easier to develop sealing properties with less heat energy and from the viewpoint of curbing blocking. An ethylene content of the component (B-1) may be 50 to 90% by mass, or may be 70 to 80% by mass.

Examples of the component (B-2) include an ethylene-acrylic acid copolymer (EAA), an ethylene-methacrylic acid copolymer (EMAA), an ethylene-methyl methacrylate copolymer (EMMA), an ethylene-ethyl acrylate copolymer (EEA), an ethylene-methyl acrylate copolymer (EMA), and an ethylene-glycidyl methacrylate-methyl acrylate copolymer (EGMA-MA). The copolymers can be used singly or in combination of two or more (as a mixture).

A proportional ethylene content of the component (B-2) may be 60 to 95% by mass, and may be 65 to 90% by mass from the viewpoint of making it easier to develop sealing properties with less heat energy and from the viewpoint of curbing blocking, and the component (B-2) may be an ethylene-methyl (meth)acrylate copolymer having such a proportional ethylene content.

A content of the component (B) may be 5 to 20% by mass, or may be 10 to 15% by mass, based on the total amount of the heat seal layer.

The heat seal layer may contain various additives such as antioxidants and lubricants that are commonly used, from the viewpoint of obtaining extrusion stability during film formation.

A total content of the components (A) and (B) in the heat seal layer may be 70 to 100% by mass or may be 90 to 100% by mass based on the total amount of the heat seal layer from the viewpoint of a reduction of the peel strength range, and the blocking resistance.

Each of the layers described above can be formed into a film by, for example, a method such as an inflation method, a T-die method, a casting method, or a calendering method. In this case, each of the components constituting each of the layers may be incorporated using a mixer such as a Henschel mixer, a tumbler mixer, or a Mazelar, and may be directly formed into a film by an extruder, or the blend may be kneaded and extruded by a single-screw or twin-screw extruder to obtain pellets, and then the pellets may be further extruded by an extruder to form a film.

The heat seal layer may be formed by a method of forming a film by extrusion molding such as inflation molding or T-die extrusion, a method of dissolving the above-described component (A), and, if necessary, component (B) and other components in a solvent and coating the film of the base layer, a method of coating as a water-based emulsion, or the like.

When a film for the heat seal layer is formed by extrusion molding, preferably, the film is co-extruded with the intermediate layer in order to improve the extrusion stability. For example, a two-layer film in which the intermediate layer and the heat seal layer are laminated can be obtained by melt-kneading a resin that forms the intermediate layer and a resin that forms the heat seal layer using separate single-screw or twin-screw extruders, laminating and integrating the two resins via a feed block or a multi-manifold die and then extruding from a T-die.

Moreover, the film for the heat seal layer obtained by extrusion molding may be laminated on the base layer by a general method such as dry laminating or extrusion laminating to form the cover tape.

An overall thickness of the cover tape may be 30 to 100 μm, may be 35 to 80 μm, and may be 40-70 μm. Within such a range, it becomes easy to ensure the strength and sealing properties of the tape.

The cover tape of the present embodiment is suitable for packaging electronic components. Examples of the electronic components include ICs, LEDs (light emitting diodes), resistors, liquid crystals, capacitors, transistors, piezoelectric element resistors, filters, crystal oscillators, crystal oscillators, diodes, connectors, switches, volumes, relays, inductors, and the like. The electronic components may be intermediate products using the components described above, or may be final products.

In the above applications, it is preferable to impart antistatic performance to the base layer and the heat seal layer in order to prevent dust attachment and to dissipate a charge of the cover tape itself. The antistatic performance can be imparted using a surfactant type, conductive metal oxide fine particles, or electron conductive polymer as a commonly used antistatic agent. Although the antistatic agent can be kneaded into the resin according to the performance to be expressed, both surface layers of the cover tape can be coated with the antistatic agent by a gravure coater or the like from the viewpoint of efficiently exhibiting effects.

The cover tape for packaging electronic components can be heat-sealed to a carrier tape, for example.

The carrier tape may have pockets for storing electronic components by a method such as air pressure molding or vacuum molding. As a material for the carrier tape, a material that can be easily formed into a sheet such as polyvinyl chloride (PVC), polystyrene (PS), polyester (A-PET, PEN, PET-G, PCTA), polypropylene (PP), polycarbonate (PC), polyacrylonitrile (PAN), acrylonitrile-butadiene-styrene copolymer (ABS) can be used. The resins can be used singly or in combination. The carrier tape may be a laminate configured of multiple layers.

The cover tape of the present embodiment can be used in combination with a carrier tape such as a carrier tape made of polystyrene or a carrier tape made of polycarbonate.

<Electronic Component Package>

An electronic component package of the present embodiment includes a carrier tape having an accommodating portion capable of accommodating electronic components, electronic components accommodated in the accommodating portion of the carrier tape, and a cover tape of the present embodiment heat-sealed to the carrier tape as a cover material.

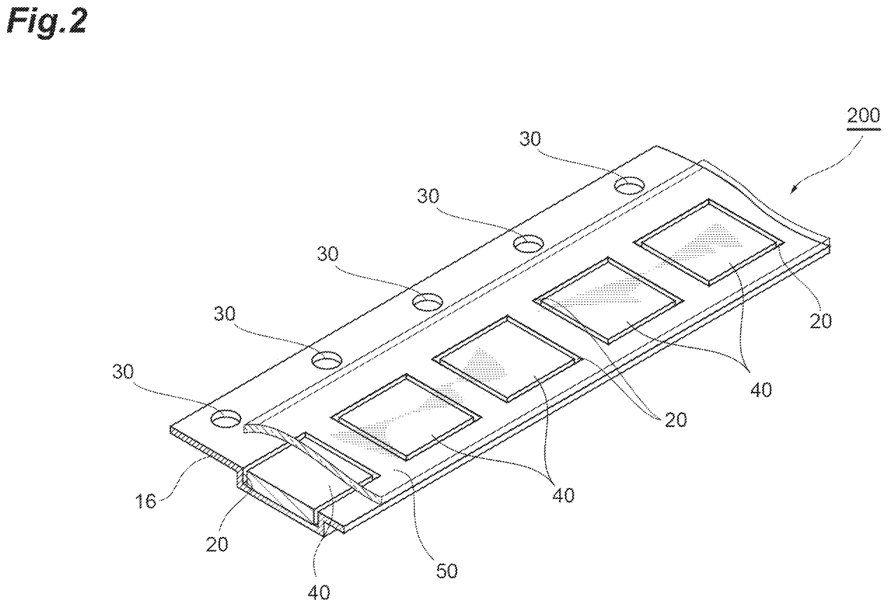

FIG. 2 is a partially cutaway perspective view showing one embodiment of the electronic component package. The electronic component package 200 shown in FIG. 2 includes an embossed carrier tape 16 having an accommodating portion 20, electronic components 40 accommodated in the accommodating portion 20, and a cover film 50 heat-sealed to the embossed carrier tape 16. Transport holes 30 that can be used for transporting various electronic components such as ICs in a sealing process are provided in the embossed carrier tape 16. Further, a hole (not shown) for electronic component inspection is provided in a bottom portion of the accommodating portion 20.

The electronic components and the carrier tape include those described above.

In the electronic component package of the present embodiment, a carrier tape wound into a reel shape can be used for storing and transporting the electronic components.

The electronic component package of the present embodiment can be manufactured by a method including a step of heat sealing the cover tape of the present embodiment to the carrier tape in which the electronic components are accommodated in the accommodating portion. Since the cover tape of the present embodiment has sufficient anti-blocking properties, even when the cover tape is wound, blocking is unlikely to occur, and it is possible to curb poor unwinding from the wound body and to efficiently perform the heat sealing process.

A member called a seal iron capable of applying a predetermined amount of heat and a predetermined pressure to the heat seal layer can be used in heat sealing of the cover tape. The cover tape can be heat-sealed to a surface of the carrier tape by pressing such a sealing iron onto the carrier tape from above the cover tape. As a specific method, a repeated sealing method in which the sealing iron is pressed a plurality of times while the embossed carrier tape is transported, or a continuous sealing method in which the heat sealing is performed while the sealing iron is continuously applied to the cover tape side can be applied.

A sealing temperature may be 100 to 240° C. or 120 to 220° C.

The electronic component package of the present embodiment can have a small peel strength range when the cover tape is peeled off. Thus, in the manufacture of electronic equipment, it is possible to greatly reduce a defective mounting rate of the electronic components.

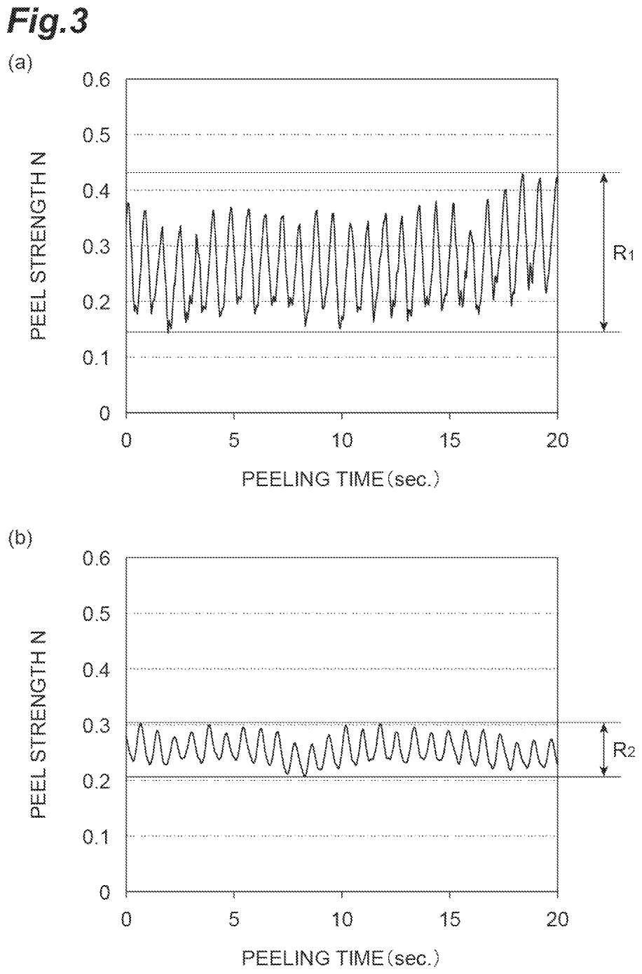

FIG. 3 is a diagram showing an example of a peel strength chart obtained when the cover tape is peeled in a longitudinal direction. In the peel strength chart shown in FIG. 3(a), the peel strength of the tape varies greatly in the longitudinal direction, and a peel strength range R₁ exceeds 0.25 N. On the other hand, in the peel strength chart shown in FIG. 3(b), a peel strength range R₂ is less than 0.15 N, and when compared with the cover tape of (a), such a cover tape is less likely to cause problems such as popping out of the electronic components due to vibration during peeling.

### EXAMPLES

Hereinafter, the present invention will be described in more detail with reference to examples and comparative examples, but the present invention is not limited to the following examples.

### Example 1

parts by mass of styrene-butadiene copolymer (manufactured by JSR Corporation, product name “TR2000”, styrene/butadiene mass ratio=40/60) as component (A-1), 25 parts by mass of styrene-butadiene copolymer (manufactured by Denka Co., Ltd., product name “Clearen 170ZR”, styrene/butadiene mass ratio=83/17) as component (A-2), 10 parts by mass of high-impact polystyrene (manufactured by Toyo Styrene Co., Ltd., product name “HIPS H870”) as component (A-3), and 20 parts by mass of an ethylene-1-butene random copolymer (manufactured by Mitsui Chemicals, Inc., product name “Tafmer A-4085 S”) as an ethylene-α-olefin copolymer were kneaded in a twin-screw extruder to obtain a resin composition constituting a heat seal layer. A two-layer film (having a total thickness of 30 μm) including a first intermediate layer (having a thickness of 20 μm) and a heat seal layer (having a thickness of μm) was obtained by co-extruding the above-described resin composition and a linear low-density polyethylene (manufactured by Ube Maruzen Polyethylene Co., Ltd., product name “Umerit 2040F”) as the first intermediate layer by a T-die method. This two-layer film was laminated with a biaxially stretched polyethylene terephthalate film (manufactured by Toyobo Co., Ltd., product name “Ester film E5100”, thickness of 16 μm) by an extrusion lamination method via a second intermediate layer (having of a thickness of 13 μm) made of a low-density polyethylene resin to obtain a cover tape of Example 1.

### Examples 2 to 12 and Comparative Examples 1 to 4

Cover tapes of Examples 2 to 12 and Comparative examples 1 to 4 were obtained in the same manner as in Example 1, except that the polystyrene-based copolymer (the (A-1) component, the (A-2) component, and the (A-3) component) and the ethylene copolymer had compositions shown in Tables 1 and 2.

The details of raw materials shown in Table 1 are as follows.

SBR: Styrene-butadiene copolymer (manufactured by JSR Corporation, product name “TR2000”, styrene/butadiene mass ratio=40/60)

SBC: Styrene-butadiene copolymer (manufactured by Denka Co., Ltd., product name “Clearen 170ZR”, styrene/butadiene mass ratio=83/17)

HIPS: High impact polystyrene (manufactured by Toyo Styrene Co., Ltd., product name “HIPS H870”)

EB: Ethylene-1-butene random copolymer (manufactured by Mitsui Chemicals, Inc., product name “Tafmer A-4085S”)

EMMA: ethylene-methyl methacrylate copolymer (manufactured by Sumitomo Chemical Co., Ltd., product name “Acryft WH303-F”, methyl methacrylate content: 18% by mass, ethylene content: 82% by mass)

The cover tapes of each of the examples and each of the comparative examples were evaluated by the following methods. Results thereof are shown in Tables 1 and 2.

[Evaluation of Peel Strength Range]

A cover tape having a width of 21.5 mm was heat-sealed to a polystyrene carrier tape having a width of 24 mm (manufactured by Denka Co., Ltd., product name: “EC-R”) to obtain a taping sample under conditions of a seal head width of 0.5 mm×2, a seal head length of 24 mm, a seal pressure of 0.5 kgf, a transport length of 12 mm, and a seal time of 0.3 seconds using a taping machine (manufactured by Nagata Seiki Co., Ltd., product name “NK-600”). A heat sealing temperature of each of the cover tapes was adjusted and determined so that an average value of the peel strength obtained from the peel strength chart was 0.4 N (±0.03 N).

The cover tape of the resulting taping sample was peeled off in the longitudinal direction at a peeling angle of 170° to 180° and a peeling speed of 300 mm/min in an atmosphere of 23° C. and a relative humidity of 50%. A difference between the maximum value and the minimum value of peel strength was calculated from the peel strength chart obtained when the cover tape is peeled off 100 mm at this time, and the peel strength range was evaluated with the following criteria.

<Determination Criteria>

A: The difference between the maximum value and the minimum value of the peel strength is less than 0.15 N
B: The difference between the maximum value and the minimum value of the peel strength is 0.15 N mN or more

[Evaluation of Blocking Resistance]

A record-wound cover tape having a width of 21.5 mm was left at rest in an atmosphere having a temperature of 23° C. and a relative humidity of 50% for 1 day, and is then unwound at a speed of 2000 mm per minute, and a load during unwinding was measured with a digital force gauge. The blocking resistance was evaluated according to the following criteria based on the load during unwinding.

<Determination Criteria>

A: A load during unwinding is less than 100 mN
B: A load during unwinding is 100 mN or more

TABLE 1

| | | | Example 1 | Example 2 | Example 3 | Example 4 | Example 5 | Example 6 | Example 7 | Example 8 |
|---|---|---|---|---|---|---|---|---|---|---|
| Polystyrene- | Component (A-1) | SBR | 45 | 55 | 45 | 45 | 45 | 50 | 45 | 45 |
| based copolymer | Component (A-2) | SBC | 25 | 30 | 35 | 35 | 25 | 35 | 35 | 35 |
| | Component (A-3) | HIPS | 10 | 5 | 10 | 5 | 10 | 5 | 5 | 10 |
| Ethylene- | Component (B-1) | EB | 20 | 10 | 10 | 15 | — | — | — | — |
| based copolymer | Component (B-2) | EMMA | — | — | — | — | 20 | 10 | 15 | 10 |

| Total (parts by mass) | | 100 | 100 | 100 | 100 | 100 | 100 | 100 | 100 |
|---|---|---|---|---|---|---|---|---|---|
| Component (A-2)/Component (A-1) | | 0.56 | 0.55 | 0.78 | 0.78 | 0.56 | 0.70 | 0.78 | 0.78 |
| Peel strength | Range (N) | 0.12 | 0.13 | 0.12 | 0.12 | 0.12 | 0.11 | 0.11 | 0.12 |
| range | Determination | A | A | A | A | A | A | A | A |
| Blocking | Load during unwinding (mN) | 99 | 90 | 75 | 95 | 97 | 84 | 91 | 68 |
| resistance | Determination | A | A | A | A | A | A | A | A |

TABLE 2

| | | | | | | | Compar- | Compar- | Compar- | Compar- |
|---|---|---|---|---|---|---|---|---|---|---|
| | | | | | | | ative | ative | ative | ative |
| | | | Example | Example | Example | Example | example | example | example | example |
| | | | 9 | 10 | 11 | 12 | 1 | 2 | 3 | 4 |
| Polystyrene- | Component (A-1) | SBR | 42 | 50 | 45 | 60 | 20 | 20 | 32.5 | 70 |
| based copolymer | Component (A-2) | SBC | 35 | 35 | 15 | 40 | 50 | 25 | 25 | 25 |
| | Component (A-3) | HIPS | 5 | 15 | 20 | — | 10 | 10 | 10 | 5 |
| Ethylene- | Component (B-1) | EB | — | — | 20 | — | 20 | — | — | — |
| based copolymer | Component (B-2) | EMMA | 18 | — | — | — | — | 45 | 32.5 | — |

| Total (parts by mass) | | 100 | 100 | 100 | 100 | 100 | 100 | 100 | 100 |
|---|---|---|---|---|---|---|---|---|---|
| Component (A-2)/Component (A-1) | | 0.83 | 0.70 | 0.33 | 0.67 | 2.50 | 1.25 | 0.77 | 0.36 |
| Peel strength | Range (N) | 0.14 | 0.14 | 0.13 | 0.13 | 0.27 | 0.18 | 0.18 | 0.12 |
| range | Determination | A | A | A | A | B | B | B | A |
| Blocking | Load during unwinding (mN) | 95 | 48 | 94 | 76 | 67 | 120 | 125 | 150 |
| resistance | Determination | A | A | A | A | A | B | B | B |

As shown in Table 1 and Table 2, it was confirmed that the cover tapes of Examples 1 to 12 in which the content of the component (A-1) is 35 to 60% by mass and the mass ratio of the component (A-2) to the component (A-1) is 0.30 to 1.0 can curb the peel strength range to 0.15 N or less while having sufficient blocking resistance.

### REFERENCE SIGNS LIST

1 Base layer
2 Heat seal layer
3, 3a, 3b Intermediate layer
16 Embossed carrier tape
20 Accommodating portion
30 Transport hole
40 Electronic component
50, 52 Cover tape
200 Electronic component package

1. A cover tape comprising:
at least a base layer, and a heat seal layer,
wherein the heat seal layer contains a copolymer (A) of a styrene-based hydrocarbon and a conjugated diene-based hydrocarbon,
the component (A) contains a block copolymer (A-1) of 10% by mass or more and less than 50% by mass of a styrene-based hydrocarbon and more than 50% by mass and 90% by mass or less of a conjugated diene-based hydrocarbon, and a block copolymer (A-2) of 50% by mass or more and 95% by mass or less of a styrene-based hydrocarbon and 5% by mass or more and 50% by mass or less of a conjugated diene-based hydrocarbon, a content of the component (A-1) is 35 to 60% by mass based on a total amount of the heat seal layer, and
a mass ratio of the component (A-2) to the component (A-1) is 0.30 to 1.0.

2. The cover tape according to claim 1, wherein the heat seal layer further contains an ethylene-based polymer (B).

3. The cover tape according to claim 2, wherein the component (B) contains one or more of an ethylene-α-olefin copolymer and an ethylene-methyl (meth)acrylate copolymer.

4. An electronic component package comprising:
a carrier tape having an accommodating portion;
electronic components accommodated in the accommodating portion of the carrier tape; and
the cover tape according to claim 1 heat-sealed to the carrier tape as a cover material.
